(19) United States
(12) Patent Application Publication
(10) Pub. No.: US 2026/0182039 A1
(43) Pub. Date: Jun. 25, 2026

(54) SEMICONDUCTOR DEVICE

(71) Applicant: Mitsubishi Electric Corporation, Tokyo (JP)

(72) Inventors: Shimon AJISAKA, Tokyo (JP); Yasuo ATA, Tokyo (JP)

(73) Assignee: Mitsubishi Electric Corporation, Tokyo (JP)

(21) Appl. No.: 19/385,118

(22) Filed: Nov. 10, 2025

(30) Foreign Application Priority Data
Dec. 20, 2024 (JP) 2024-225137

(51) Int. Cl. H10D 87/00; H01L 23/31; H10D 1/47; H10D 10/60; H10D 12/00; H10D 30/66; H10D 62/832

(52) U.S. Cl. CPC H10D 87/00; H10D 1/47; H10W 74/137; H10D 10/60; H10D 12/441; H10D 30/66; H10D 62/8325

(57) ABSTRACT

Provided is a semiconductor device in which controllability of false turn-on is improved. A semiconductor device according to the present disclosure includes a power element, an active mirror clamp element, a gate signal pad, and an active mirror clamp signal pad. The active mirror clamp element is provided on a semiconductor substrate in which the power element is formed via an insulting film. A first current electrode of the active mirror clamp element is electrically connected to the gate electrode of the power element, and a second current electrode of the active mirror clamp element is electrically connected to one current electrode of the power element. The gate signal pad is electrically connected to the gate electrode of the power element. The active mirror clamp signal pad is electrically connected to a control electrode of the active mirror clamp element.

### BACKGROUND

### Technical Field

The present disclosure relates to a semiconductor device.

### Description of the Background Art

A protection design is an important element as a design element of a power element. Floating of gate voltage is one of factors that the power element needs to be protected. For example, when a value of gate voltage is higher than a predetermined value by displacement current occurring in a steep switching process, false turn-on occurs. A semiconductor device described in Japanese Patent Application Laid-Open No. 2016-174033 suppresses occurrence of false turn-on by an active mirror clamp circuit.

### SUMMARY

When the active mirror clamp circuit is provided to an SiC circuit, achievement of ohmic contact is blocked by a Schottky barrier formed between a p-type SiC region formed by implanting impurity and a metal electrode, for example, and a function of controlling the false turn-on of the mirror clamp circuit is reduced.

An object of the present disclosure is to provide a semiconductor device in which controllability of false turn-on is improved.

A semiconductor device according to the present disclosure includes a power element, an active mirror clamp element, a gate signal pad, and an active mirror clamp signal pad. The power element is formed in a semiconductor substrate. The active mirror clamp element is a lateral element formed on the semiconductor substrate via an insulating film. The gate signal pad is electrically connected to a gate electrode of the power element. The active mirror clamp signal pad is provided independently from the gate signal pad, and is electrically connected to a control electrode of the active mirror clamp element. A first current electrode of the active mirror clamp element is electrically connected to the gate electrode of the power element. A second current electrode of the active mirror clamp element is electrically connected to one current electrode of the power element.

Provided is a semiconductor device in which controllability of false turn-on is improved.

These and other objects, features, aspects and advantages of the present disclosure will become more apparent from the following detailed description of the present disclosure when taken in conjunction with the accompanying diagrams.

### BRIEF DESCRIPTION OF THE DRAWINGS

FIG. 1 is a cross-sectional view illustrating a configuration of a semiconductor device according to an embodiment 1.

FIG. 2 is a circuit diagram illustrating a configuration of the semiconductor device.

FIG. 3 is a cross-sectional view illustrating a configuration of a semiconductor device according to an embodiment 2.

FIG. 4 is a circuit diagram illustrating a configuration of the semiconductor device.

FIG. 5 is a cross-sectional view illustrating a configuration of a semiconductor device according to an embodiment 3.

FIG. 6 is a circuit diagram illustrating a configuration of the semiconductor device.

FIG. 7 is a cross-sectional view illustrating a configuration of a semiconductor device according to an embodiment 4.

FIG. 8 is a circuit diagram illustrating a configuration of the semiconductor device.

### DESCRIPTION OF THE PREFERRED EMBODIMENTS

### Embodiment 1

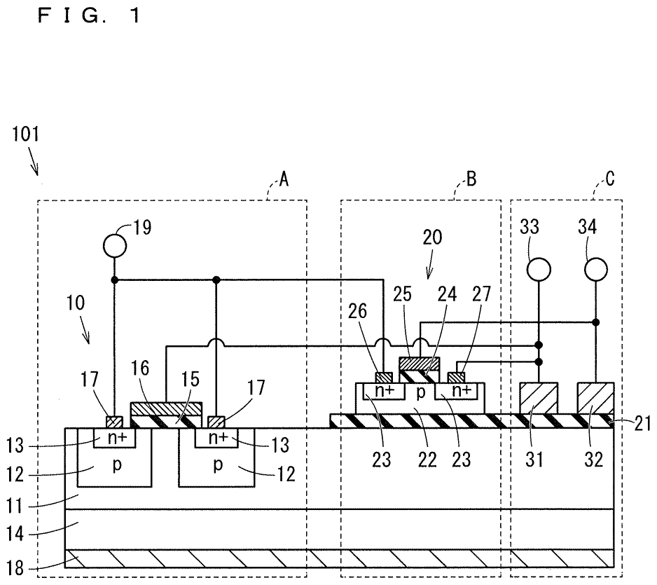

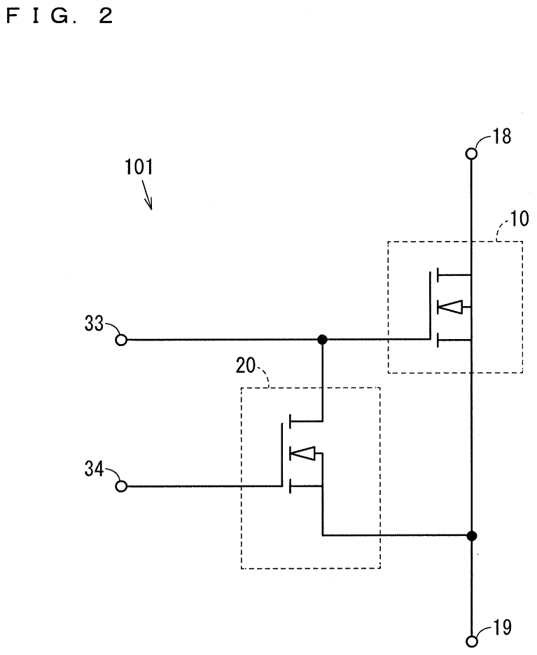

FIG. 1 is a cross-sectional view illustrating a configuration of a semiconductor device 101 according to an embodiment 1. FIG. 2 is a circuit diagram illustrating the configuration of the semiconductor device 101.

The semiconductor device 101 includes an element region A, an active mirror clamp circuit region B, and a wiring region C in one semiconductor chip. A vertical metal-oxide semiconductor field-effect transistor (MOSFET) is provided as a power element 10 to the element region A. A lateral MOSFET is provided as an active mirror clamp element 20 to the active mirror clamp circuit region B. The active mirror clamp element 20 is a switching element different from the power element 10, and is provided in the semiconductor chip in which the power element 10 is formed. In other words, the active mirror clamp element 20 is built in the semiconductor chip in which the power element 10 is formed.

The vertical MOSFET as the power element 10 is formed of SiC. The vertical MOSFET includes an n⁻type drift layer 11, a p-type well region 12, an n⁺-type well region 13, an n⁺-type drain layer 14, an insulating film 15, a gate electrode 16, a source electrode 17, and a drain electrode 18. The SiC substrate is made up of the n⁻type drift layer 11, the p-type well region 12, the n⁺-type well region 13, and the n⁺-type drain layer 14.

The n⁻type drift layer 11 is provided on a side of a front surface of the SiC substrate. The p-type well region 12 is provided to a part of a surface layer of the n⁻type drift layer 11. The n⁺-type well region 13 is provided to a part of a surface layer of the p-type well region 12. The n⁻type drift layer 11, the p-type well region 12, and the n⁺-type well region 13 are exposed from the front surface of the SiC substrate.

The insulating film 15 is provided to the front surface of the n⁻type drift layer 11, the p-type well region 12, and the n⁺-type well region 13 constituting the front surface of the SiC substrate. The insulating film 15 according to the embodiment 1 covers the p-type well region 12 and the n⁻type drift layer 11 located between the n⁺-type well region 13 on a left side and the n⁺-type well region 13 on a right side in FIG. 1. The gate electrode 16 is provided on the insulating film 15. The source electrode 17 is electrically connected to the n⁺-type well region 13 while having contact therewith constituting the front surface of the SiC substrate.

The n⁺-type drain layer 14 is provided on a side of a back surface of the SiC substrate. The drain electrode 18 is electrically connected to the n⁺-type drain layer 14 while having contact therewith constituting the back surface of the SiC substrate.

A plurality of cells (not shown) are regularly disposed in the element region A. The vertical MOSFET is formed in each of the plurality of cells. However, a shape and an arrangement of each cell are not limited thereto in a configuration in FIG. 1.

The active mirror clamp circuit region B includes a field oxide film 21 and the active mirror clamp element 20. The field oxide film 21 is provided on the n⁻type drift layer 11 constituting the front surface of the SiC substrate.

The active mirror clamp element 20 is provided on the field oxide film 21, and is formed of polysilicon. The active mirror clamp element 20 according to the embodiment 1 is an N-channel enhancement-type MOSFET. The N-channel enhancement-type MOSFET includes a p-type poly-Si layer 22, an n⁺-type poly-Si region 23, an insulating film 24, a gate electrode 25, a source electrode 26, and a drain electrode 27.

The p-type poly-Si layer 22 is provided on the field oxide film 21. The n⁺-type poly-Si region 23 is provided in a part of a surface layer of the p-type poly-Si layer 22. Two n⁺-type poly-Si regions 23 are provided herein. As illustrated in FIG. 1, the insulating film 24 covers a surface of the p-type poly-Si layer 22 located between the n⁺-type poly-Si region 23 on a left side and the n⁺-type poly-Si region 23 on a right side. The gate electrode 25 is provided on the insulating film 24. The source electrode 26 is electrically connected to the n⁺-type poly-Si region 23 on the left side while having contact therewith in two n+-type poly-Si regions 23. The drain electrode 27 is electrically connected to the n⁺-type poly-Si region 23 on the right side while having contact therewith.

The wiring region C includes a gate voltage wiring 31, an active mirror clamp circuit signal wiring 32, a gate signal pad 33, and an active mirror clamp signal pad 34. The gate voltage wiring 31 and the active mirror clamp circuit signal wiring 32 are provided on the field oxide film 21. Although the gate signal pad 33 and the active mirror clamp signal pad 34 are pads different from each other, but are provided in the same semiconductor chip. In other words, the active mirror clamp signal pad 34 is provided in the semiconductor chip independently from the gate signal pad 33.

The gate signal pad 33 is electrically connected to the gate electrode 16 of the power element 10 and the drain electrode 27 of the active mirror clamp element 20 via the gate voltage wiring 31. That is to say, the drain electrode 27 of the active mirror clamp element 20 is electrically connected to the gate electrode 16 of the power element 10.

The active mirror clamp signal pad 34 is electrically connected to the gate electrode 25 of the active mirror clamp element 20 via the active mirror clamp circuit signal wiring 32.

The source electrode 26 of the active mirror clamp element 20 is electrically connected to the source electrode 17 of the power element 10. The source electrode 26 of the active mirror clamp element 20 and the source electrode 17 of the power element 10 are connected to a source terminal 19.

In an ON operation of the semiconductor device 101, positive bias is applied to the gate signal pad 33, and negative bias is applied to the active mirror clamp signal pad 34. Since positive bias gate voltage is applied to the gate electrode 16 of the power element 10, the power element 10 is operated. Since negative bias control voltage is applied to the gate electrode 25 of the active mirror clamp element 20, the active mirror clamp element 20 is not operated.

In an OFF operation of the semiconductor device 101, negative bias is applied to the gate signal pad 33, and positive bias is applied to the active mirror clamp signal pad 34. Since positive bias control voltage is applied to the gate electrode 16 of the active mirror clamp element 20, the active mirror clamp element 20 is operated. As a result, the gate electrode 16 and the source electrode 17 of the power element 10 are in a short-circuit state via the active mirror clamp element 20. Thus, false turn-on of the power element 10 is prevented.

To sum up the above, the semiconductor device 101 according to the embodiment 1 includes the power element 10, the active mirror clamp element 20, the gate signal pad 33, and the active mirror clamp signal pad 34. The power element 10 is formed in the SiC substrate as he semiconductor substrate. The active mirror clamp element 20 includes the MOSFET as the lateral element formed on the semiconductor substrate via the field oxide film as the insulating film. The gate signal pad 33 is electrically connected to the gate electrode 16 of the power element 10. The active mirror clamp signal pad 34 is provided independently from the gate signal pad 33, and is electrically connected to the gate electrode 25 as a control electrode of the active mirror clamp element 20. The drain electrode 27 as a first current electrode of the active mirror clamp element 20 is electrically connected to the gate electrode 16 of the power element 10. The source electrode 26 as a second current electrode of the active mirror clamp element 20 is electrically connected to the source electrode 17 as one current electrode of the power element 10.

According to such a semiconductor device 101, controllability of false turn-on is improved. The active mirror clamp element 20 is formed of polysilicon on the SiC substrate. Since the active mirror clamp element 20 is not formed by implanting impurity into the SiC substrate, a negative effect caused by a Schottky barrier between the p-type SiC region formed by implanting the impurity and a metal electrode does not occur.

### Embodiment 2

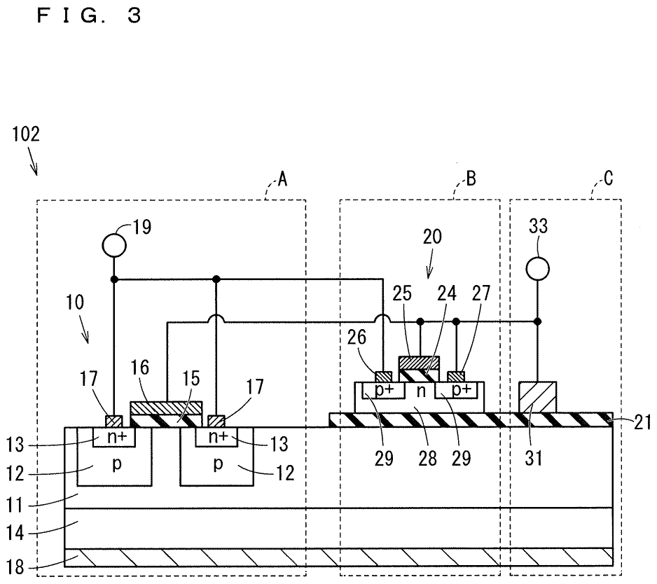

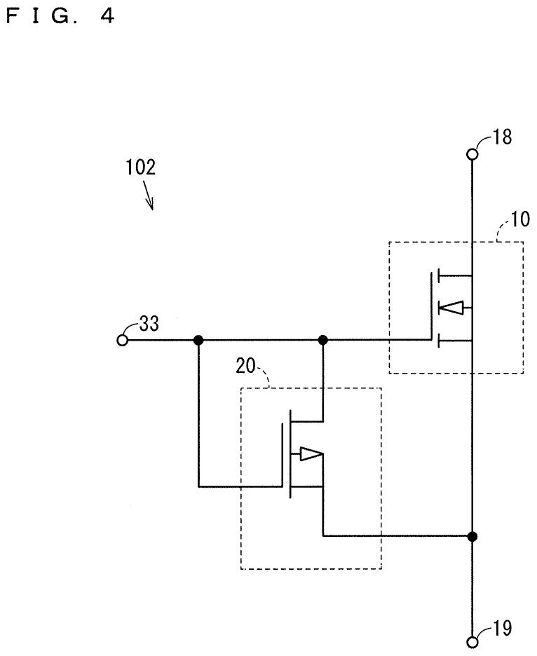

FIG. 3 is a cross-sectional view illustrating a configuration of a semiconductor device 102 according to an embodiment 2. FIG. 4 is a circuit diagram illustrating the configuration of the semiconductor device 102.

A vertical MOSFET is provided as the power element 10 to the element region A. The vertical MOSFET has the same configuration as the embodiment 1.

The active mirror clamp circuit region B includes the field oxide film 21 and the active mirror clamp element 20. The field oxide film 21 is provided on the n⁻type drift layer 11 constituting the front surface of the SiC substrate.

The active mirror clamp element 20 is a switching element different from the power element 10, and is a lateral MOSFET. The active mirror clamp element 20 is provided on the field oxide film 21, and is provided in the semiconductor chip in which the power element 10 is formed. The active mirror clamp element 20 according to the embodiment 2 is a P-channel depression-type MOSFET.

The P-channel depression-type MOSFET is formed of polysilicon. The P-channel depression-type MOSFET includes an n-type poly-Si layer 28, a p⁺-type poly-Si region 29, the insulating film 24, the gate electrode 25, the source electrode 27, and the drain electrode 26.

The n-type poly-Si layer 28 is provided on the field oxide film 21. The p⁺-type poly-Si region 29 is provided in a part of a surface layer of the n-type poly-Si layer 28. Two p⁺-type poly-Si regions 29 are provided herein. As illustrated in FIG. 3, the insulating film 24 covers a surface of the n-type poly-Si layer 28 located between the p⁺-type poly-Si region 29 on a left side and the p⁺-type poly-Si region 29 on a right side. The gate electrode 25 is provided on the insulating film 24. The source electrode 27 is electrically connected to the p⁺-type poly-Si region 29 on the right side while having contact therewith in two p⁺-type poly-Si regions 29. The drain electrode 26 is electrically connected to the p⁺-type poly-Si region 29 on the left side while having contact therewith.

The wiring region C includes the gate voltage wiring 31 and the gate signal pad 33. The gate voltage wiring 31 is provided on the field oxide film 21. The gate signal pad 33 is provided in the semiconductor chip.

The gate signal pad 33 is electrically connected to the gate electrode 16 of the power element 10 and the gate electrode 25 and the source electrode 27 of the active mirror clamp element 20 via the gate voltage wiring 31. That is to say, the gate electrode 25 and the source electrode 27 of the active mirror clamp element 20 are electrically connected to the gate electrode 16 of the power element 10.

The drain electrode 26 of the active mirror clamp element 20 is electrically connected to the source electrode 17 of the power element 10.

In an ON operation of the semiconductor device 102, positive bias is applied to the gate signal pad 33. Accordingly, positive bias is applied to the gate electrode 16 of the power element 10 and the gate electrode 25 of the active mirror clamp element 20. The power element 10 is operated by application of the positive bias. However, the active mirror clamp element 20 is the P-channel depression-type MOSFET, thus is not operated.

In an OFF operation of the semiconductor device 102, negative bias is applied to the gate signal pad 33. Accordingly, negative bias is applied to the gate electrode 25 of the active mirror clamp element 20. The active mirror clamp element 20 is the P-channel depression-type MOSFET, thus is operated. As a result, the gate electrode 16 and the source electrode 17 of the power element 10 are in a short-circuit state via the active mirror clamp element 20. Thus, false turn-on of the power element 10 is prevented.

In such a semiconductor device 102, a drive power source for operating the power element 10 the active mirror clamp element 20 are commonalized, and a drive power source for the active mirror clamp element is unnecessary.

### Embodiment 3

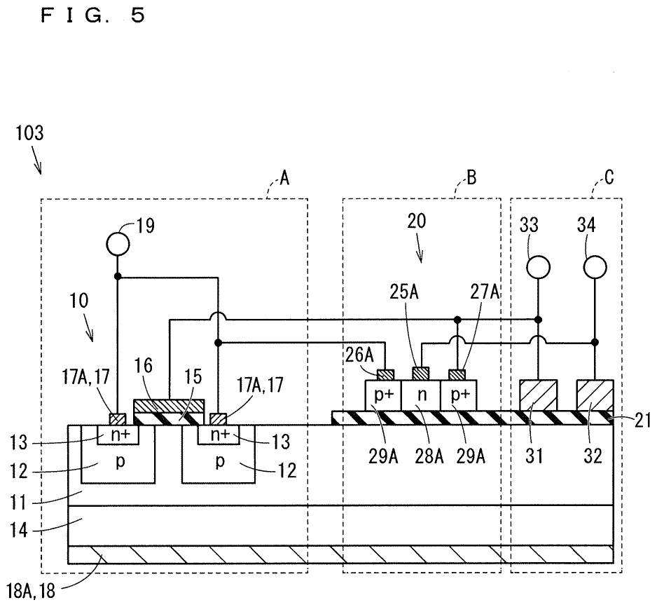

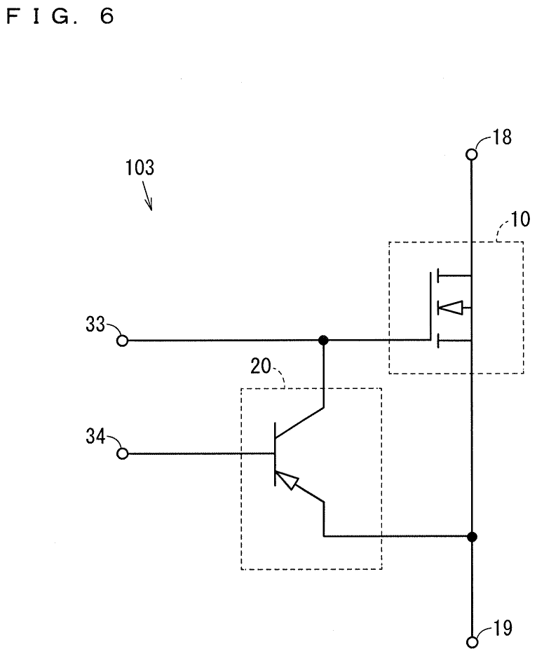

FIG. 5 is a cross-sectional view illustrating a configuration of a semiconductor device 103 according to an embodiment 3. FIG. 6 is a circuit diagram illustrating the configuration of the semiconductor device 103.

A vertical MOSFET is provided as the power element 10 to the element region A. The vertical MOSFET has the same configuration as the embodiment 1.

The active mirror clamp circuit region B includes the field oxide film 21 and the active mirror clamp element 20. The field oxide film 21 is provided on the n⁻type drift layer 11 constituting the front surface of the SiC substrate.

The active mirror clamp element 20 is a switching element different from the power element 10, and is a lateral bipolar transistor. The active mirror clamp element 20 is provided on the field oxide film 21, and is provided in the semiconductor chip in which the power element 10 is formed.

The lateral bipolar transistor as the active mirror clamp element 20 is formed of polysilicon, for example. The lateral transistor is a pnp transistor including an n-type semiconductor region 28A, a p⁺-type semiconductor region 29A, a base electrode 25A as a control electrode, an emitter electrode 26A as a second current electrode, and a collector electrode 27A as a first current electrode.

The n-type semiconductor region 28A and the p⁺-type semiconductor region 29A are provided on the field oxide film 21. Herein, two p⁺-type semiconductor regions 29A are provided to sandwich the n-type semiconductor region 28A therebetween. The base electrode 25A is provided on the n-type semiconductor region 28A. As illustrated in FIG. 5, the emitter electrode 26A is electrically connected to the p⁺-type semiconductor region 29A on the left side while having contact therewith in two p⁺-type semiconductor regions 29A. The collector electrode 27A is electrically connected to the p⁺-type semiconductor region 29A on the right side while having contact therewith in two p⁺-type semiconductor regions 29A.

The active mirror clamp element 20 controls current flowing between the emitter electrode 26A and the collector electrode 27A by control voltage applied between the base electrode 25A and the emitter electrode 26A.

The wiring region C includes the gate voltage wiring 31, the active mirror clamp circuit signal wiring 32, the gate signal pad 33, and the active mirror clamp signal pad 34. The gate voltage wiring 31 and the active mirror clamp circuit signal wiring 32 are provided on the field oxide film 21. Although the gate signal pad 33 and the active mirror clamp signal pad 34 are pads different from each other, but are provided in the same semiconductor chip. In other words, the active mirror clamp signal pad 34 is provided in the semiconductor chip independently from the gate signal pad 33.

The gate signal pad 33 is electrically connected to the gate electrode 16 of the power element 10 and the collector electrode 27A of the active mirror clamp element 20 via the gate voltage wiring 31. That is to say, the collector electrode 27A of the active mirror clamp element 20 is electrically connected to the gate electrode 16 of the power element 10.

The active mirror clamp signal pad 34 is electrically connected to the base electrode 25A of the active mirror clamp element 20 via the active mirror clamp circuit signal wiring 32.

The emitter electrode 26A of the active mirror clamp element 20 is electrically connected to the source electrode 17 of the power element 10.

In an ON operation of the semiconductor device 103, positive bias is applied to the gate signal pad 33, and negative bias is applied to the active mirror clamp signal pad 34. Since positive bias gate voltage is applied to the gate electrode 16 of the power element 10, the power element 10 is operated. Since negative bias control voltage is applied to the base electrode 25A of the active mirror clamp element 20, the active mirror clamp element 20 is not operated.

In an OFF operation of the semiconductor device 103, negative bias is applied to the gate signal pad 33, and negative bias is applied to the active mirror clamp signal pad 34. Since negative bias control voltage is applied to the base electrode 25A of the active mirror clamp element 20, the active mirror clamp element 20 is operated. Since the gate electrode 16 and the source electrode 17 of the power element 10 are in a short-circuit state via the active mirror clamp element 20, false turn-on of the power element 10 is prevented.

The power element 10 may be a vertical insulated-gate bipolar transistor (IGBT). In this case, the n⁺-type drain layer 14 illustrated in FIG. 5 is replaced with the p⁺-type collector layer. A first main electrode 17A of the power element 10 corresponds to an emitter electrode, and a second main electrode 18A thereof corresponds to a collector electrode. This configuration is also applied to the above embodiments 1 and 2 and a subsequent embodiment 4 in the similar manner. When the power element 10 is the IGBT, achieved is the semiconductor device 103 which can be used with high voltage in a large current region.

### Embodiment 4

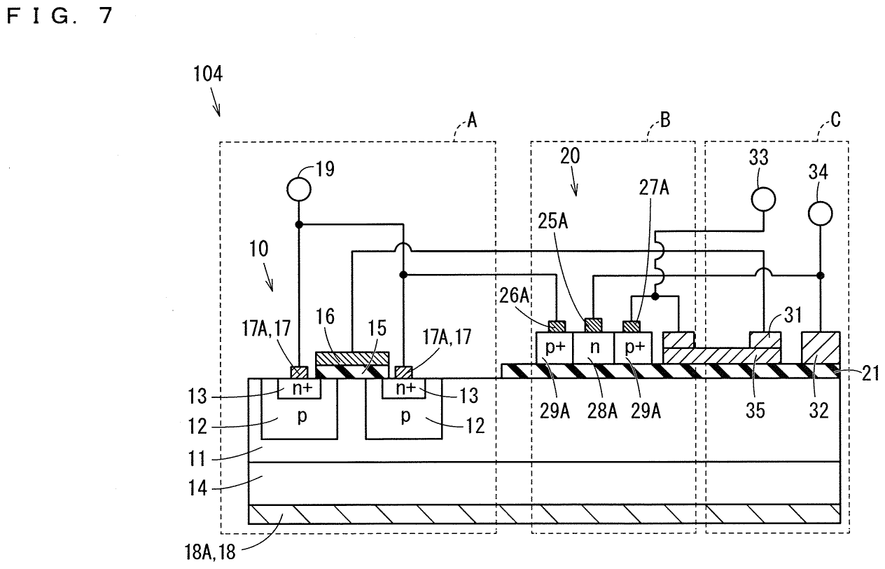

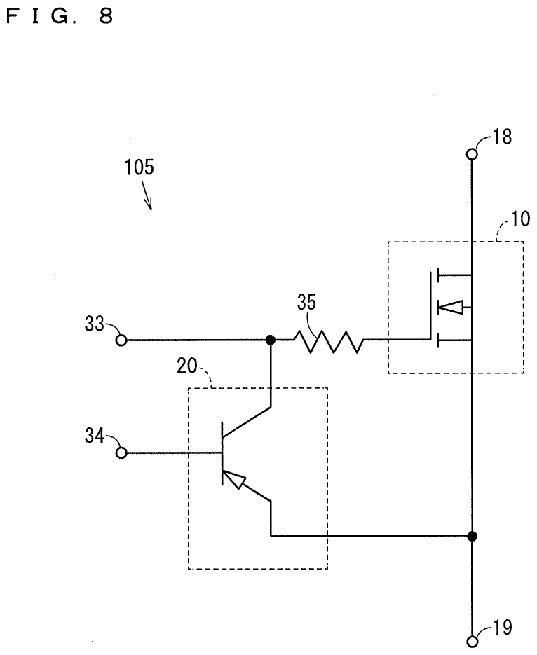

FIG. 7 is a cross-sectional view illustrating a configuration of a semiconductor device 104 according to an embodiment 4. FIG. 8 is a circuit diagram illustrating the configuration of the semiconductor device 104.

The power element 10 is provided to the element region A. The power element 10 illustrated in FIG. 7 is the vertical MOSFET. That is to say, the vertical MOSFET according to the embodiment 4 has the same configuration as the embodiment 1.

The active mirror clamp circuit region B includes the field oxide film 21 and the active mirror clamp element 20. The field oxide film 21 is provided on the n⁻type drift layer 11 constituting the front surface of the SiC substrate.

The active mirror clamp element 20 is the switching element different from the power element 10, and is the lateral transistor. The active mirror clamp element 20 is provided on the field oxide film 21, and is provided in the semiconductor chip in which the power element 10 is formed. The lateral transistor according to the embodiment 4 is a pnp transistor having the same configuration as the embodiment 3. This embodiment can also be applied to the embodiment 1 or the embodiment 2.

An on-chip gate resistor 35 attached to a gate of the power element 10 is provided in the wiring region C. One end of the on-chip gate resistor 35 is connected to the collector electrode 27A of the active mirror clamp element 20. The other end of the on-chip gate resistor 35 is connected to the gate electrode 16 of the power element 10.

Even when the on-chip gate resistor 35 is included in the chip, the resistor is prevented and false turn-on can be controlled according to the present embodiment.

In the present disclosure, each embodiment can be arbitrarily combined, or each embodiment can be appropriately varied or omitted.

The aspects of the present disclosure are collectively described hereinafter as appendixes.

### Appendix 1

A semiconductor device, comprising:
a power element formed in a semiconductor substrate;
an active mirror clamp element as a lateral element formed on the semiconductor substrate via an insulating film;
a gate signal pad electrically connected to a gate electrode of the power element; and
an active mirror clamp signal pad provided independently from the gate signal pad and electrically connected to a control electrode of the active mirror clamp element, wherein
a first current electrode of the active mirror clamp element is electrically connected to the gate electrode of the power element, and
a second current electrode of the active mirror clamp element is electrically connected to one current electrode of the power element.

### Appendix 2

A semiconductor device, comprising:
a power element formed in a semiconductor substrate; and
an active mirror clamp element including a P-channel depression-type lateral MOSFET formed on the semiconductor substrate via an insulating film, wherein
a gate electrode of the active mirror clamp element is electrically connected to a gate electrode of the power element,
a drain electrode of the active mirror clamp element is electrically connected to the gate electrode of the power element, and
a source electrode of the active mirror clamp element is electrically connected to one current electrode of the power element.

### Appendix 3

The semiconductor device according to Appendix 1 or 2, further comprising
an on-chip gate resistor, wherein
one end of the on-chip gate resistor is connected to the first current electrode or the drain electrode of the active mirror clamp element, and
another end of the on-chip gate resistor is connected to the gate electrode of the power element.

### Appendix 4

The semiconductor device according to any one of Appendixes 1 to 3, wherein
the power element is a transistor of any one of a vertical IGBT and a vertical MOSFET.

### Appendix 5

The semiconductor device according to any one of Appendixes 1, 3, and 4, wherein
the active mirror clamp element is a lateral enhancement-type MOSFET or a lateral bipolar transistor.

### Appendix 6

The semiconductor device according to any one of Appendixes 1 to 5, wherein
the semiconductor substrate in which the power element is formed is an SiC substrate, and the insulating film on the semiconductor substrate is a field oxide film, and
the active mirror clamp element is formed of polysilicon provided on the field oxide film.

While the disclosure has been shown and described in detail, the foregoing description is in all aspects illustrative and not restrictive. It is therefore understood that numerous modifications and variations can be devised.

What is claimed is:

1. A semiconductor device, comprising:
a power element formed in a semiconductor substrate;
an active mirror clamp element as a lateral element formed on the semiconductor substrate via an insulating film;
a gate signal pad electrically connected to a gate electrode of the power element; and
an active mirror clamp signal pad provided independently from the gate signal pad and electrically connected to a control electrode of the active mirror clamp element, wherein
a first current electrode of the active mirror clamp element is electrically connected to the gate electrode of the power element, and
a second current electrode of the active mirror clamp element is electrically connected to one current electrode of the power element.

2. A semiconductor device, comprising:
a power element formed in a semiconductor substrate; and
an active mirror clamp element including a P-channel depression-type lateral MOSFET formed on the semiconductor substrate via an insulating film, wherein
a gate electrode of the active mirror clamp element is electrically connected to a gate electrode of the power element,
a drain electrode of the active mirror clamp element is electrically connected to the gate electrode of the power element, and
a source electrode of the active mirror clamp element is electrically connected to one current electrode of the power element.

3. The semiconductor device according to claim 1, further comprising
an on-chip gate resistor, wherein
one end of the on-chip gate resistor is connected to the first current electrode of the active mirror clamp element, and
another end of the on-chip gate resistor is connected to the gate electrode of the power element.

4. The semiconductor device according to claim 2, further comprising
an on-chip gate resistor, wherein
one end of the on-chip gate resistor is connected to the drain electrode of the active mirror clamp element, and
another end of the on-chip gate resistor is connected to the gate electrode of the power element.

5. The semiconductor device according to claim 1, wherein
the power element is a transistor of any one of a vertical IGBT and a vertical MOSFET.

6. The semiconductor device according to claim 2, wherein
the power element is a transistor of any one of a vertical IGBT and a vertical MOSFET.

7. The semiconductor device according to claim 1, wherein
the active mirror clamp element is a lateral enhancement-type MOSFET or a lateral bipolar transistor.

8. The semiconductor device according to claim 1, wherein
the semiconductor substrate in which the power element is formed is an SiC substrate, and the insulating film on the semiconductor substrate is a field oxide film, and
the active mirror clamp element is formed of polysilicon provided on the field oxide film.

9. The semiconductor device according to claim 2, wherein
the semiconductor substrate in which the power element is formed is an SiC substrate, and the insulating film on the semiconductor substrate is a field oxide film, and
the active mirror clamp element is formed of polysilicon provided on the field oxide film.
